(19) United States
(12) Patent Application Publication
(10) Pub. No.: US 2014/0175439 A1
(43) Pub. Date: Jun. 26, 2014

(54) SEMICONDUCTOR INTEGRATED CIRCUIT AND MULTI-CHIP PACKAGE INCLUDING THE SAME

(71) Applicant: SK HYNIX INC., Gyeonggi-do (KR)

(72) Inventor: Tae-Yong LEE, Gyeonggi-do (KR)

(73) Assignee: SK HYNIX INC., Gyeonggi-do (KR)

(21) Appl. No.: 13/844,911

(22) Filed: Mar. 16, 2013

(30) Foreign Application Priority Data
Dec. 20, 2012 (KR) 10-2012-0149782

(51) Int. Cl. H01L 21/66

(52) U.S. Cl. CPC H01L 22/32
USPC 257/48

(57) ABSTRACT

In an aspect of the present invention, a semiconductor integrated circuit includes a semiconductor chip including a through-chip via, a probe pad disposed in such a way as not to overlap with the through-chip via, and a connection part electrically coupling the probe pad and the through-chip via

### CROSS-REFERENCE TO RELATED APPLICATIONS

The present application claims priority of Korean Patent Application No. 10-2012-0149782, filed on Dec. 20, 2012, which is incorporated herein by reference in its entirety.

### BACKGROUND

1. Field

Exemplary embodiments of the present invention relate to semiconductor design technology, and more particularly, to a semiconductor integrated circuit capable of providing a probe test and a multi-chip package (hereinafter referred to as an ‘MCP’) including the same.

2. Description of the Related Art

In general, a semiconductor device, such as double data rate synchronous DRAM (DDR SDRAM), is developing in different kinds of directions in order to satisfy the needs of users. One of the developing directions includes package technology. There is being proposed an MCP as package technology for semiconductor devices, The MCP refers to forming a plurality of semiconductor chips into one chip. The capacity of memory may be increased using a plurality of memory chips having a memory function, or desired performance may be improved using a semiconductor integrated circuit having different functions. For reference, the MCP may be divided into a single-layered type MCP and a multi-layered type MCP depending on its construction. In the single-layered type MCP, a plurality of semiconductor chips is disposed on a plane in parallel, whereas in the multi-layered type MCP, a plurality of semiconductor chips is stacked on a plane.

Meanwhile, if a plurality of semiconductor integrated circuits is implemented in the form of a multi-layered type MCP, the I/O terminals of each of semiconductor chips were subject to wire bonding. If wire bonding is used, however, there are disadvantages in terms of a high-speed operation and different kinds of noises. For this reason, chip-on-chip package technology is now being used instead of the wire bonding technology.

The chip-on-chip package technology is package technology for directly connecting a plurality of semiconductor chips by bumps and through silicon vias (hereinafter referred to as ‘TSVs’). In this technology, a plurality of semiconductor integrated circuits may be stacked vertically even without a wire. If the chip-on-chip package technology is used, a high-speed operation may be possible and consumption power may be reduced, Furthermore, the chip-on-chip package technology is one of the spotlight technologies because a total area of the MCP may be minimized.

A bump used in the chip-on-chip package technology may be designed in a very small size. When performing a test operation using a probe pin (hereinafter referred to as a ‘probe test operation’), however, it may be difficult to bring the probe pin into contact with the bump having a small size. As a result, an addition probe pad having a size greater than that of the bump may be designed in order to normally perform the probe test operation.

FIG. 1 is a diagram illustrating a conventional semiconductor integrated circuit.

Referring to FIG. 1, the semiconductor integrated circuit includes a TSV 110, and a probe pad 120 is directly connected to the TSV 110. When performing a probe test operation, a tester performs different kinds of test operations by probing the probe pad 120 with a probe pin 130 connected to a probe test card.

FIG. 2 is a diagram illustrating an MCP in which the semiconductor integrated circuits of FIG. 1 are stacked.

Referring to FIG. 2, the MCP is formed by stacking first to fourth semiconductor chips 210, 220, 230, and 240, such as those shown in FIG. 1, The TSVs, the probe pads, and the bumps of the first to fourth semiconductor chips 210, 220, 230, and 240 are overlapped with each other and coupled.

Referring back to FIG. 1, when performing a probe test operation, the probe pad 120 may be directly brought into contact with the probe pin 130. Accordingly, a surface of the probe pad 120 may be damaged by the probe pin 130. If the probe pad 120 is damaged, it may be difficult to form a bump on the probe pad 120.

### SUMMARY

An exemplary embodiment of the present invention is directed to providing a semiconductor integrated circuit that may minimize the influence of a probe test operation on other circuits,

Another exemplary embodiment of the present invention is directed to providing an MCP that may fundamentally remove various methods occurring when performing a probe test operation.

In accordance with an exemplary embodiment of the present invention, a semiconductor integrated circuit may include a semiconductor chip including a through-chp via, a probe pad disposed in such a way as not to overlap the through-chip via, and a connection part electrically coupling the probe pad and the through-chip via,

The connection part preferably may be controlled in such a way as to be connected or disconnected.

In accordance with another exemplary embodiment of the present invention, an MCP may include a plurality of semiconductor chips including through-chip vias, bumps overlapped with the through-chip vias and electrically coupling the plurality of semiconductor chips, probe pads disposed in such a way as not to overlap the bumps, and connection parts electrically coupling the probe pads and the through-chip vias.

The plurality of semiconductor chips preferably may be spaced apart from each other at an interval corresponding to the size of the bump.

In accordance with yet another exemplary embodiment of the present invention, an MCP may include a plurality of semiconductor chips including through-chip vias, a probe pad overlapped with the through vias, wherein the probe pad includes a probe region having a predetermined area and regions other than the probe region, and a plurality of bumps overlapped with the regions other than the probe region and electrically coupling the through-chip vias.

Preferably, each of the plurality of semiconductor chips may include a plurality of the through-chip vias, and the plurality of through-chip vias may be overlapped with the regions other than the probe region.

In the semiconductor integrated circuit in accordance with one embodiment of the present invention, the influence of a probe test operation on other circuits may be minimized because the probe pad for the probe test operation is disposed at a predetermined place.

Furthermore, the MCP in accordance with one embodiment of the present invention may guarantee a stable circuit operation when performing a normal operation because a bump is stably formed although a probe pad may be damaged when performing a probe test operation.

### BRIEF DESCRIPTION OF THE DRAWINGS

FIG. 1 is a diagram illustrating a conventional semiconductor integrated circuit.

FIG. 2 is a diagram illustrating an MCP in which the semiconductor integrated circuits of FIG. 1 are stacked.

FIG. 3 is a diagram illustrating a semiconductor integrated circuit in accordance with one embodiment of the present invention.

FIG. 4 is a diagram illustrating an MCP in accordance with one embodiment of the present invention,

FIG. 5 is a diagram illustrating another form of connection between TSVs and a probe pad in accordance with one embodiment of the present invention,

FIG. 6 is a diagram illustrating an MCP in accordance with another embodiment of the present invention,

FIG. 7 is a further detailed diagram showing the structure of FIG. 6.

FIG. 8 is a diagram showing a structure extended from the structure of FIG. 7.

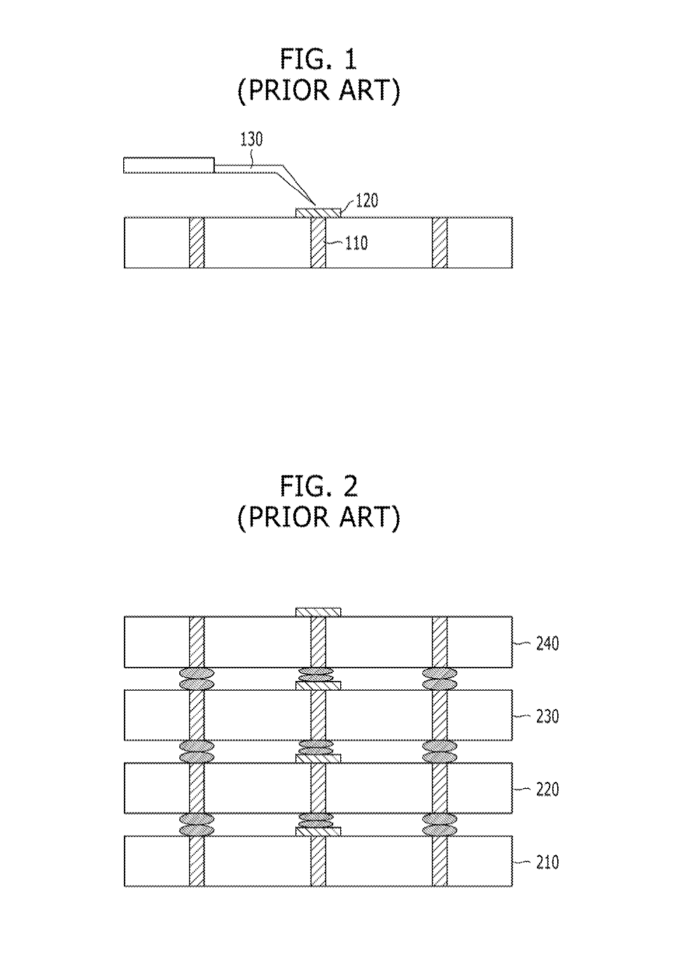

### DETAILED DESCRIPTION

Exemplary embodiments of the present invention will be described below in more detail with reference to the accompanying drawings. The present invention may, however, be embodied in different forms and should not be construed as limited to the embodiments set forth herein, Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween.

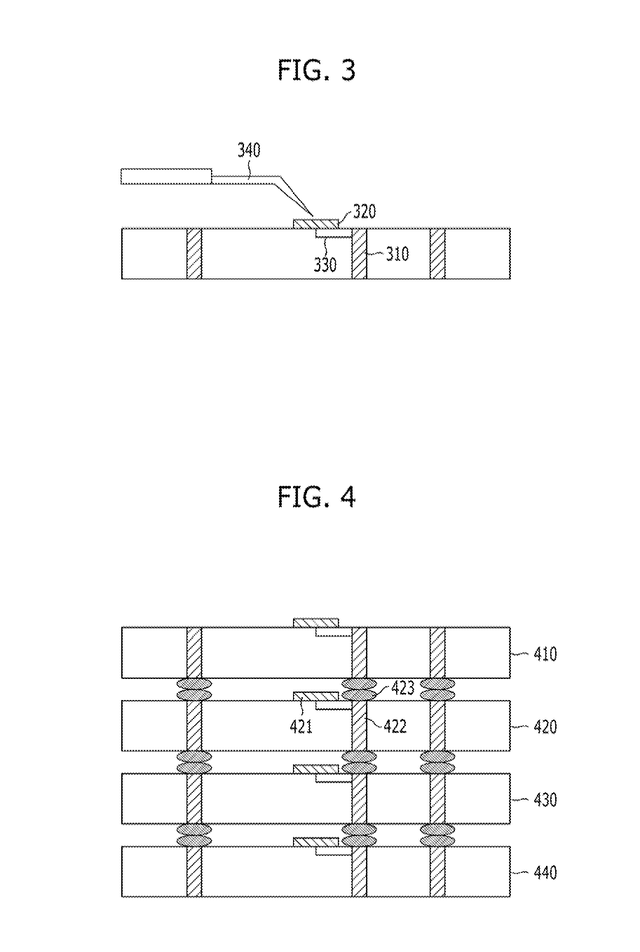

FIG. 3 is a diagram illustrating a semiconductor integrated circuit in accordance with one embodiment of the present invention.

Referring to FIG. 3, the semiconductor integrated circuit includes a TSV 310 a probe pad 320 disposed in such a way not to overlap the TSV 310, and a connection part 330 electrically coupling the TSV 310 and the probe pad 320. The connection part 330 may be a wire for connecting the TSV 310 and the probe pad 320 and may be connected or disconnected depending on the design.

In the semiconductor integrated circuit in accordance with one embodiment of the present invention, the TSV 310 and the probe pad 320 are electrically coupled by the connection part 330. Accordingly, when performing a probe test operation, a test operation on the TSV 310 may be performed by probing the probe pad 320 with a probe pin 340.

Meanwhile, in the semiconductor integrated circuit in accordance with one embodiment of the present invention, although the probe pad 320 is damaged when performing a probe test operation, there may be almost no influence due to the damaged probe pad 320 in using the TSV 310. For example, if an MCP is formed by stacking semiconductor integrated circuits, a bump, not the damaged probe pad 320, may be connected to the TSV 310. In other words, the probe pad 320 may not give any influence in connecting a bump to the TSV 310.

FIG. 4 is a diagram illustrating an MCP in accordance with one embodiment of the present invention.

Referring to FIG. 4, the MCP is formed by stacking first to fourth semiconductor chips 410, 420, 430, and 440, such as those shown in FIG. 3. Elements corresponding to the second semiconductor chip 420 are described as an example, for convenience of description. As described above, in the second semiconductor chip 420 in accordance with one embodiment of the present invention, a probe pad 421 does not overlap a bump 423 because it does not overlap a TSV 422. The bump 423 is disposed in such a way as to overlap with the TSV 422, and the first and second semiconductor chips 410 and 420 are electrically coupled by the bump 423.

In the MCP in accordance with one embodiment of the present invention, although a probe pad is damaged when performing a probe test operation, connection between a TSV and a bump may not be influenced. Furthermore, in the MCP in accordance with one embodiment of the present invention, all bumps may be formed to have the same size. In this case, the first to fourth semiconductor chips 410, 420, 430, and 440 are spaced apart from each other at an interval corresponding to the size of the bump.

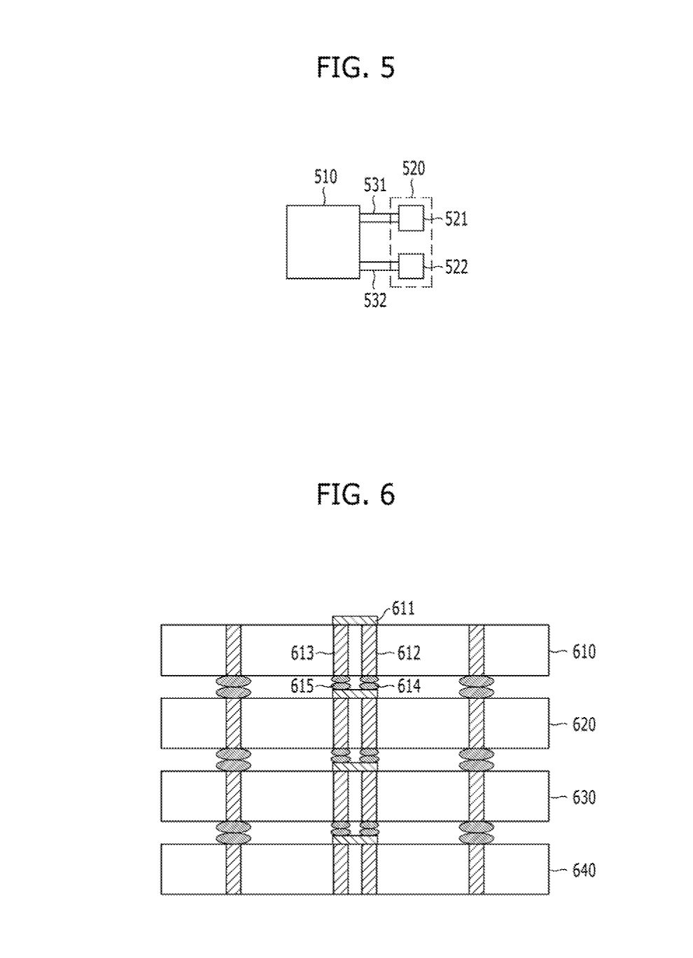

FIG. 5 is a diagram illustrating another form of connection between TSVs and a probe pad in accordance with one embodiment of the present invention.

Referring to FIG. 5, one probe pad 510 may be connected to a plurality of TSVs 520. In FIG. 5, first and second TSVs 521 and 522 are illustrated as being disposed on one side of the probe pad 510, for convenience of description. The first and the second TSVs 521 and 522 are connected to first and second connection parts 531 and 532, respectively. The first and the second connection parts 531 and 532 may also be connected or disconnected depending on the design.

In accordance with one embodiment of the present invention, the number and arrangement of probe pads and TSVs may be different depending on the design. In this case, the influence of a probe pad, damaged when a performing a probe test operation, on a TSV may be further minimized.

FIG. 6 is a diagram illustrating an MCP in accordance with another embodiment of the present invention.

Referring to FIG. 6, the MCP is formed by stacking first to fourth semiconductor chips 610, 620, 630, and 640. Elements corresponding to the first semiconductor chips 610 are described as an example, for convenience of description.

In the MCP in accordance with one embodiment of the present invention, a probe pad 611 is disposed in such a way as to overlap first and second TSVs 612 and 613, and the first and second TSVs 612 and 613 are connected to first and second bumps 614 and 615, respectively. Accordingly, the first and the second bumps 614 and 615 are overlapped with the probe pad 611.

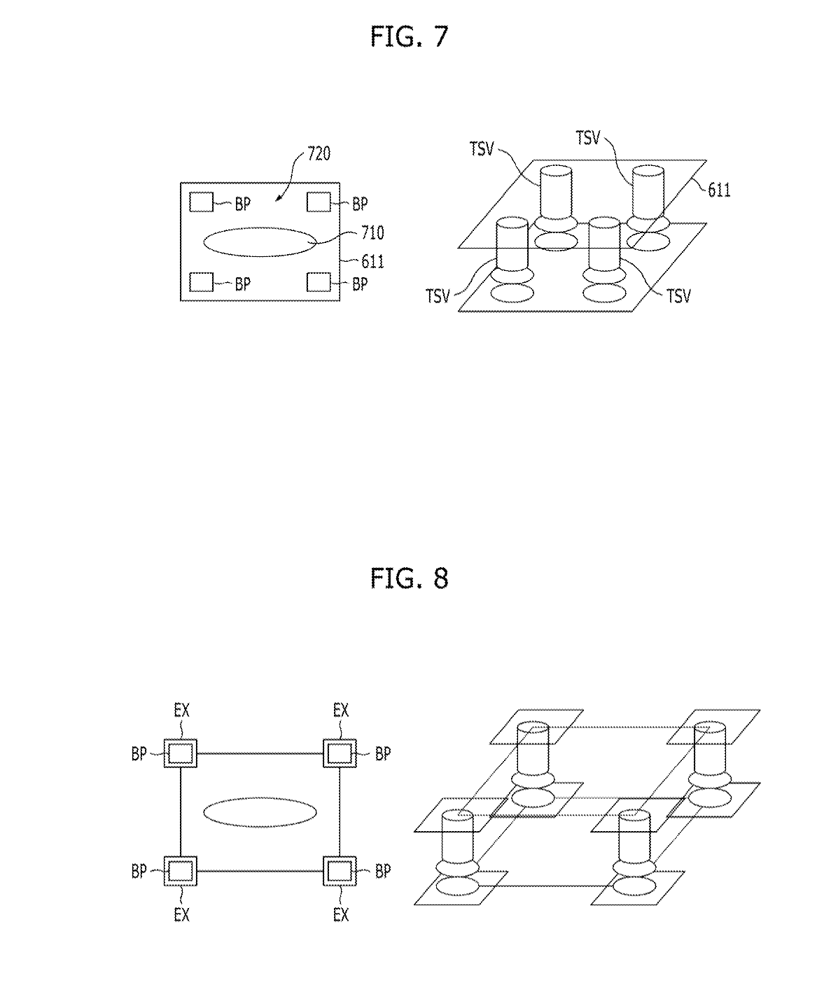

FIG. 7 is a further detailed diagram showing the structure of FIG. 6. The probe pad 611 is divided into a probe region 710 and the remaining region 720.

Referring to FIG. 7, the probe region 710 of the probe pad 611 has a direct contact with a probe pin, and bump pads BP are overlapped with TSVs and disposed in the remaining region 720 other than the probe region 710. In Fig, 7, four TSVs and four bump pads BP are illustrated as being overlapped with each other and disposed at the respective corners of one probe pad, for example, the probe pad 611. The bump pad BP means a pad to which a bump is substantially connected.

FIG. 8 is a diagram showing a structure extended from the structure of FIG. 7.

Unlike in FIG. 7, in FIG. 8, extension regions EX are added, and bump pads BP are overlapped with the respective extension regions EX. In FIG. 8, four TSVs and four bump pads BP are illustrated as being overlapped with each other and disposed in the respective extension regions EX.

In the MCP in accordance with the embodiments of the present invention of FIGS. 7 and 8, the bumps are disposed in the respective regions other than the probe region of the probe pad. Thus, the influence of a probe test operation on the bumps and the TSVs may be minimized.

As described above, in the semiconductor integrated circuits and the MCPs in accordance with the embodiments of the present invention, a probe pad for a probe test operation is disposed at a predetermined place. As a result, the influence of a probe test operation on other circuits may be minimized, and thus reliability of a circuit operation in the semiconductor integrated circuit and the MCP may be improved.

Furthermore, there is an advantage in that reliability of a circuit operation in the semiconductor integrated circuit and the MCP may be improved by guaranteeing a stable normal operation after performing a probe test operation.

The locations and types of the logic gates and the transistors illustrated in the aforementioned embodiments may be differently implemented depending on the polarity of an input signal.

While the present invention has been described with respect to the specific embodiments, it will be apparent to those skilled in the art that various changes and modifications may be made without departing from the spirit and scope of the invention as defined in the following claims.

What is claimed is:

1. A semiconductor integrated circuit comprising:
a semiconductor chip including a through-chip via;
a probe pad disposed not to overlap the through-chip via; and
a connection part configured to electrically couple the probe pad and the through-chip via.

2. The semiconductor integrated circuit of claim 1 wherein the connection part is disposed between the probe pad and the through-chip via.

3. A multi-chip package, comprising:
a plurality of semiconductor chips, each including a number of through-chip vias;
bumps configured to be overlapped with the respective through-chip vias and electrically couple the plurality of semiconductor chips;
probe pads disposed not to overlap the respective bumps; and
connection parts configured to electrically couple the probe pads and the through-chip vias.

4. The multi-chip package of claim 3 further comprising bump pads connecting each of the semiconductor chips and the bumps.

5. The multi-chip package of claim wherein the plurality of semiconductor chips are spaced apart from each other at an interval corresponding to a size of the bumps.

6. The multi-chip package of claim wherein the connection parts are configured to be connected or disconnected to the probe pads and the through-chip vias.

7. A multi-chip package, comprising:
a plurality of semiconductor chips including a plurality of through-chip vias;
a probe pad coupled to a number of through-chip vias with the through-chip vias, wherein the probe pad includes a probe region having a predetermined area and regions other than the probe region; and
a plurality of bumps, each bump coupled to the corresponding through-via other than the probe region and electrically coupled to the through-chip vias.

8. The multi-chip package of claim 7, wherein the through-chip vias are overlapped with the regions other than the probe region.

9. The multi-chip package of claim 8, wherein the plurality of bumps are overlapped with the respective through vias.

10. The multi-chip package of claim 9, further comprising a plurality of bump pads connecting the plurality of semiconductor chips and the plurality of bumps.

11. The multi-chip package of claim 7, wherein the regions other than the probe region comprise extension regions.

12. The multi-chip package of claim 11, wherein the plurality of bumps are overlapped with the extension regions.

13. The multi-chip package of claim 11, wherein the through-chip vias are overlapped with the extension regions,

14. A semiconductor integrated circuit comprising:
a semiconductor chip including a plurality of through-chip vias; and
a plurality of probe pads, each probe pad configured to be contacted by a probe pin and electrically coupling a predetermined number of the through-chip vias.

15. The semiconductor integrated circuit of claim 14, wherein each probe pad comprises a probe region configured to be contacted by the probe pin and a remaining region overlapped with the predetermined number of the through-chip vias.

16. The semiconductor integrated circuit claim 14, wherein each probe pad comprises:
a probe region configured to be contacted by the probe pin;
a predetermined number of extended regions being overlapped with the predetermined number of the through-chip vias; and
a remaining region electrically coupling the extended regions to the probe region.
